(19) United States
(12) Patent Application Publication
(10) Pub. No.: US 2019/0064950 A1
(43) Pub. Date: Feb. 28, 2019

(54) FOLDABLE ELECTRONIC DEVICE AND CONTROL METHOD THEREOF

(71) Applicant: INT TECH CO., LTD., HSINCHU COUNTY (TW)

(72) Inventor: KUO-CHENG HSU, TAICHUNG CITY (TW)

(21) Appl. No.: 15/685,652

(22) Filed: Aug. 24, 2017

(51) Int. Cl. G06F 3/041; G06F 1/16; G01R 27/26

(52) U.S. Cl. CPC G06F 3/041; G01R 27/2605; G06F 1/1616

(57) ABSTRACT

A foldable electronic device includes a first electronic component, a first sensing electrode, a second electronic component, a second sensing electrode and a foldable component. The first sensing electrode is disposed in the first electronic component. The second sensing electrode is disposed in the second electronic component. The foldable component is connected between the first electronic component and the second electronic component. The foldable component is configured for folding the first electronic component with respect to the second electronic component about an axis. A capacitance is formed between the first sensing electrode and the second sensing electrode, and a folding angle between the first electronic component and the second electronic component is determined based on a value of the capacitance between the first sensing electrode and the second sensing electrode.

### BACKGROUND

A foldable electronic device such as a foldable touch device has been developed due to its slim size and intuitive interaction between the user and the device. The foldable touch device may be applied to various kinds of electronic apparatus such as smart phone, notebook computer or the like. The foldable electronic device may be operated in different states such as an unfolded state and several folded states with different folding angles for different applications.

### SUMMARY

Embodiments of the present invention provide a foldable electronic component. The foldable electronic device includes a first electronic component, a first sensing electrode, a second electronic component, a second sensing electrode and a foldable component. The first electronic component includes a first surface and a second surface opposite to the first surface. The first sensing electrode is disposed in the first electronic component. The second electronic component includes a third surface and a fourth surface opposite to the third surface. The second sensing electrode is disposed in the second electronic component. The foldable component is connected between the first electronic component and the second electronic component. The foldable component is configured for folding the first electronic component with respect to the second electronic component about an axis. A capacitance is formed between the first sensing electrode and the second sensing electrode, and a folding angle between the first electronic component and the second electronic component is determined based on a value of the capacitance between the first sensing electrode and the second sensing electrode.

In some embodiments, the first surface, the second surface, the third surface and the fourth surface are flat surfaces.

In some embodiments, the first electronic component comprises a first touch component configured to implement touch input function from the first surface.

In some embodiments, the first electronic component comprises a second touch component configured to implement touch input function from the second surface.

In some embodiments, the second electronic component comprises a third touch component configured to implement touch input function from the third surface.

In some embodiments, the second electronic component comprises a fourth touch component configured to implement touch input function from the fourth surface.

In some embodiments, the foldable component further includes a fifth surface connected between the second surface and the fourth surface, and a fifth touch component configured to implement touch input function from the fifth surface.

In some embodiments, when the folding angle is substantially equal to 180 degrees, the fifth surface is a flat surface.

In some embodiments, when the folding angle is smaller than 180 degrees, the fifth surface is a curve surface.

In some embodiments, the first electronic component further includes a first curve surface connected between the first surface and the second surface, and a first curve touch component configured to implement touch input function from the first curve surface.

In some embodiments, the second electronic component further includes a second curve surface connected between the third surface and the fourth surface, and a second curve touch component configured to implement touch input function from the second curve surface.

In some embodiments, the foldable electronic device further includes at least one display panel disposed in the first electronic component and the second electronic component, and configured to display images from the first surface, the second surface, the third surface and the third surface.

Embodiments of the present invention provide a method for controlling a foldable electronic device. The method includes detecting the value of the capacitance between the first sensing electrode and the second sensing electrode; and determining the folding angle between the first electronic component and the second electronic component based on the value of the capacitance between the first sensing electrode and the second sensing electrode.

In some embodiments, the method further includes sending a transmitting signal to the first sensing electrode, and receiving a receiving signal by the second sensing electrode.

In some embodiments, the foldable electronic device comprises a foldable touch device, and the method further comprises enabling a respective touch input mode according to the folding angle between the first electronic component and the second electronic component.

In some embodiments, the foldable electronic device comprises a foldable display device, and the method further comprises switching the foldable electronic device to a respective display mode according to the folding angle between the first electronic component and the second electronic component.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A, FIG. 1B, FIG. 1C, FIG. 1D, FIG. 1E, FIG. 1F and FIG. 1G are schematic diagrams illustrating a foldable electronic device having different folding angles;

FIG. 2 is a schematic diagram of a foldable electronic device in accordance with some embodiments of the present disclosure;

FIG. 3 is a flow chart illustrating a method for controlling a foldable electronic device according to various aspects of one or more embodiments of the present disclosure; and

FIG. 4 is a flow chart illustrating a method for controlling a foldable electronic device according to various aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Further, spatially relative terms, such as “beneath,” “below,” “lower,” “above,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second” and “third” when used herein do not imply a sequence or order unless clearly indicated, by the context.

In some embodiments of the present disclosure, a foldable electronic component includes one or more first sensing electrode and one or more second sensing electrode disposed in the first and second electronic components, respectively. The folding angle of the foldable electronic device can be determined by detecting the value of capacitance between the first sensing electrode and the second sensing electrode. The foldable electronic component thus can be automatically switched to respective operational mode such as respective touch input mode and/or display mode according to the detected folding angle to meet the user's requirement.

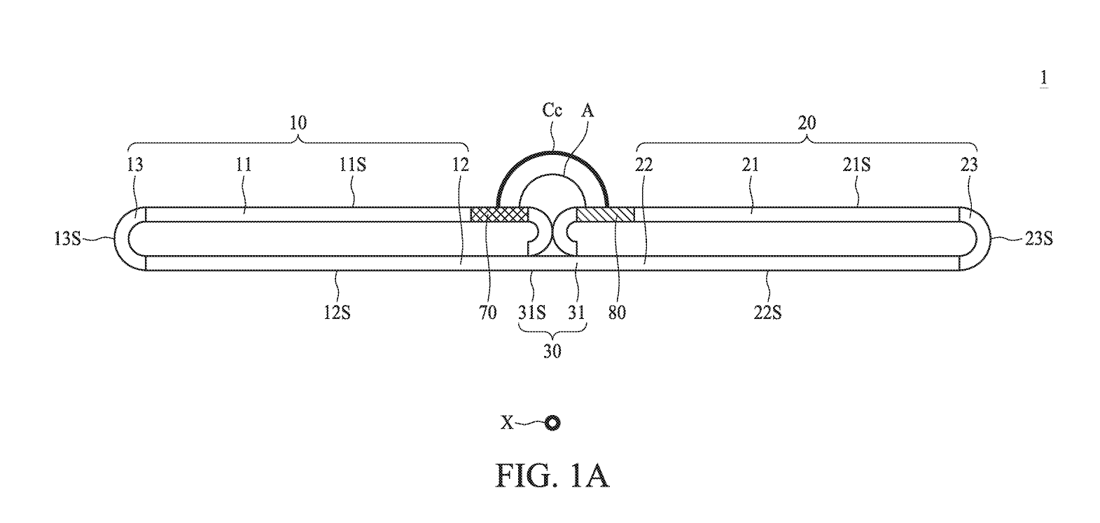

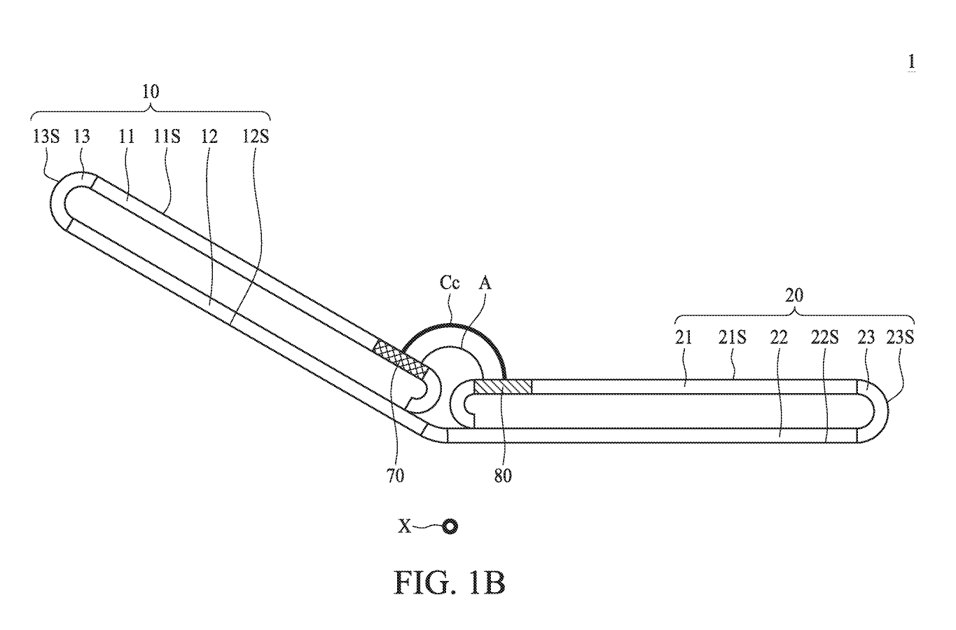

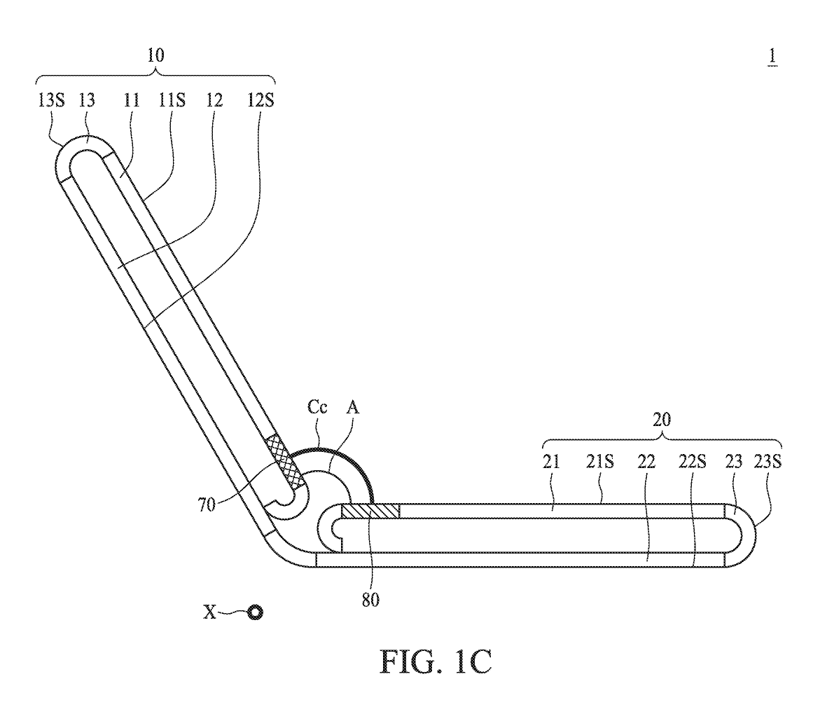

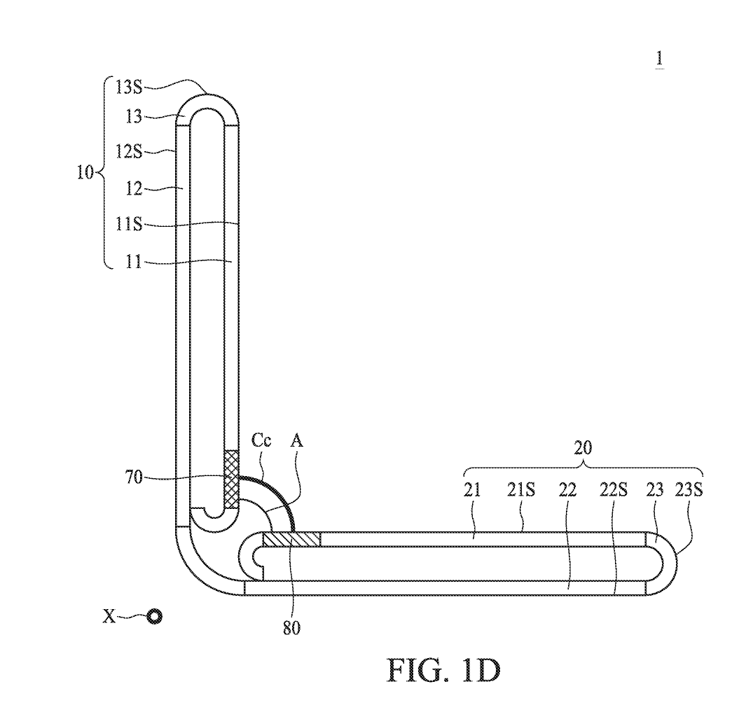

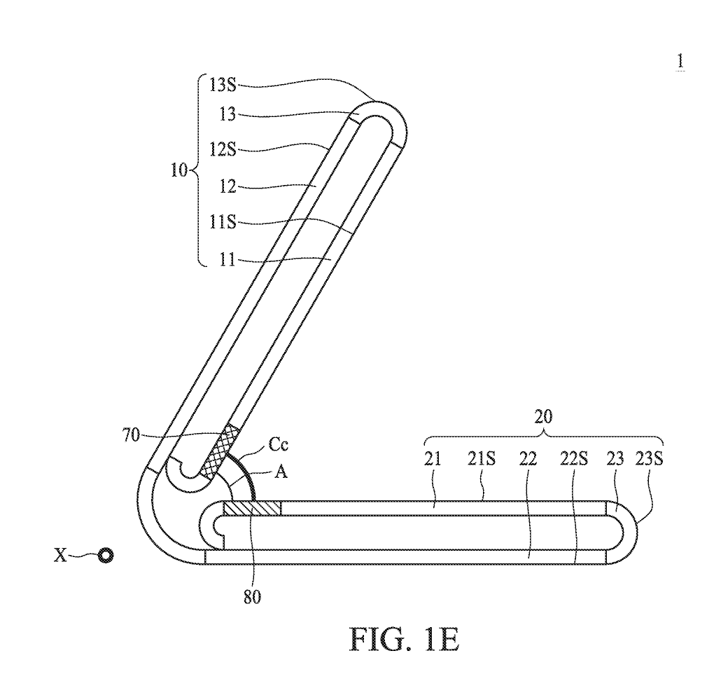

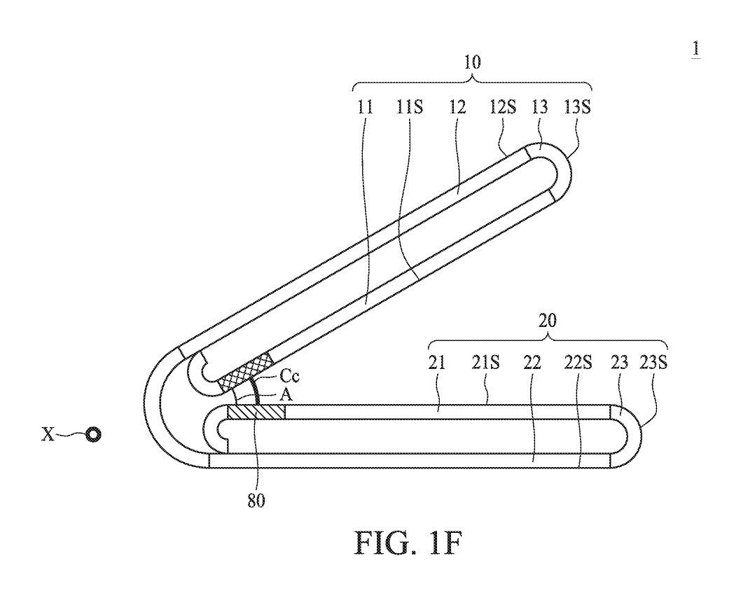

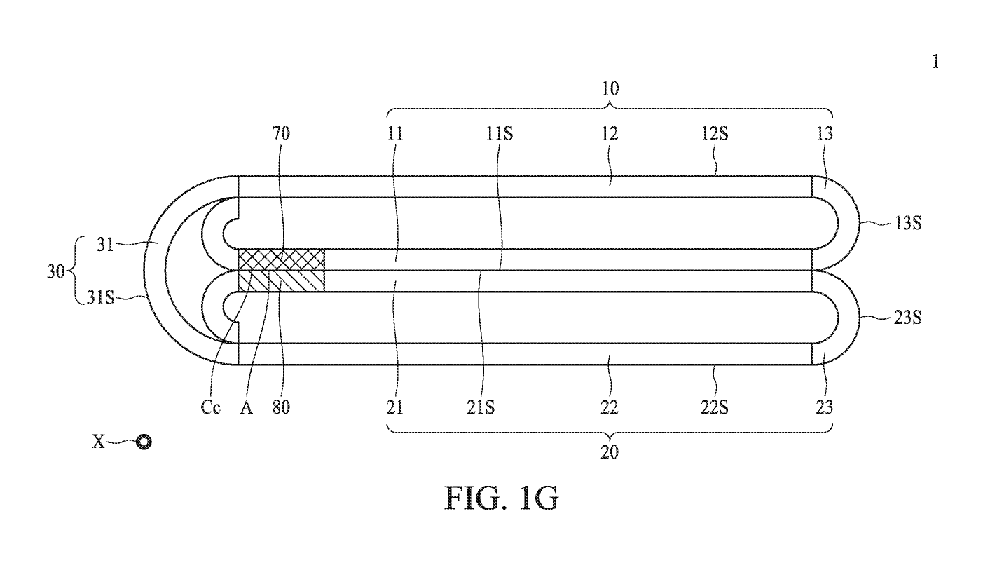

FIG. 1A, FIG. 1B, FIG. 1C, FIG. 1D, FIG. 1E, FIG. 1F and FIG. 1G are schematic diagrams illustrating a foldable electronic device having different folding angles. As depicted in FIG. 1A, FIG. 1B, FIG. 1C, FIG. 1D, FIG. 1E, FIG. 1F and FIG. 1G, the foldable electronic device 1 includes a first electronic component 10, a first sensing electrode 70, a second electronic component 20, a second sensing electrode 80 and a foldable component 30. The first electronic component 10 includes a first surface 11S and a second surface 12S opposite to the first surface 11S. In some embodiments, the first sensing electrode 70 is disposed in the first electronic component 10. By way of example, the first sensing electrode 70 is disposed adjacent to the first surface 11S. The second electronic component 2C) includes a third surface 21S and a fourth surface 22S opposite to the third surface 215. In some embodiments, the second sensing electrode 80 is disposed in the second electronic component 20. By way of example, the second sensing electrode 80 is disposed adjacent to the second surface 21S. The foldable component 30 is connected between the first electronic component 10 and the second electronic component 20. In some embodiments, each of the first electronic component 10 and the second electronic component 20 may be rigid, flexible or bendable. In some embodiments, the first surface 11S, the second surface 12S, the third surface 21S and the fourth surface S may be flat surfaces, but are not limited thereto.

In some embodiments, the first electronic component 10 may include a touch panel such as a capacitive touch panel. In some embodiments, the first electronic component 10 may include a first touch component 11 configured to implement touch input function from the first surface 11S. In some embodiments, the first electronic component 10 may further include a second touch component 12 configured to implement touch input function from the second surface 12S. In some embodiments, the second electronic component 20 may include a touch panel such as a capacitive touch panel. In some embodiments, the second electronic component 20 may include a third touch component 21 configured to implement touch input function from the third surface 21S. In some embodiments, the second electronic component 20 may further include a fourth touch component 22 configured to implement touch input function from the fourth surface 22S.

The foldable component 30 is configured for folding the first electronic component 10 with respect to the second electronic component 20 about an axis X to switch among different states such that a folding angle A may exist between the first electronic component 10 and the second electronic component 20. In some embodiments, the folding angle A may be varied in different states as shown in FIG. 1A, FIG. 1B FIG. 1C, FIG. 1D, FIG. 1E, FIG. 1F and FIG. 1G. In some embodiments, the foldable component 30 is pivotally mounted on the first electronic component 10 and the second electronic component 20 such that the first electronic component 10 and the second electronic component 20 may be folded with respect to each other. In some alternative embodiments, the foldable component 30 may be connected to the first electronic component 10 and the second electronic component 20 in other foldable or rotatable manners. In some embodiments, the foldable component 30 may further include a fifth touch component 31 configured to implement touch input function from a fifth surface 31S connected between the second surface 12S and the fourth surface 22S. In some embodiments, the fifth surface 31S may be formed from an extendable material, which may be extended in folded states. By way of examples, the fifth surface 315 may be a flat surface when the folding angle A is substantially equal to 180 degrees. In some embodiments, the fifth surface 31S may be a curve surface when the folding angle A is smaller than 180 degrees.

In some embodiments, the first electronic component 10 may further include a first curve touch component 13 configured to implement touch input function from a first curve surface 13S connected between the first surface 11S and the second surface 12S. In some embodiments, the second electronic component 20 may further include a second curve touch component 23 configured to implement touch input function from a second curve surface 23S connected between the third surface 21S and the fourth surface 22S. In some embodiments, each of the first curve surface 13S and second curve surface 23S may have a fixed curvature, but is not limited thereto. In some embodiments, the first surface IIS, the first curve surface 135 and the second surface 12S may be connected in a seamless manner such that the user may implement touch input at any locations of the first electronic component 10. Similarly, the the third surface 215, the second curve surface 23S and the fourth surface 22S may be connected in a seamless manner such that the user may implement touch input at any locations of the second electronic component 20.

In some embodiments, the foldable electronic device 1 may be folded in different states in different applications. A capacitance Cc may be formed between the first sensing electrode 70 and the second sensing electrode 80, and the value of the capacitance Cc is substantially inversely proportional to the folding angle A between the first sensing electrode 70 and the second sensing electrode 80. For example, a lower value of the capacitance Cc reflects a larger folding angle A between the first sensing electrode 70 and the second sensing electrode 80, and a higher value of the capacitance Cc reflects a smaller folding angle A between the first sensing electrode 70 and the second sensing electrode 80. Therefore, the folding angle A can he calculated based on the value of the capacitance detected by a processor (not shown). Accordingly, when the user folds the foldable electronic device 1, the folding angle A can be detected, and a respective touch input mode may be enabled according to the folding angle A to meet the user's requirement. For example, when the foldable electronic device 1 is unfolded as shown in FIG. 1A, the touch function of the first surface 11S, the second surface 12S, the third surface 21S and the fourth surface 22S can be enabled. When the foldable electronic device 1 is folded at a folding angle A of about 90 degrees as shown in 1D, the touch input function of the first surface 11S and the third surface 21S can be enabled, while the touch input function of the second surface 125 and the fourth surface 22S can be disabled.

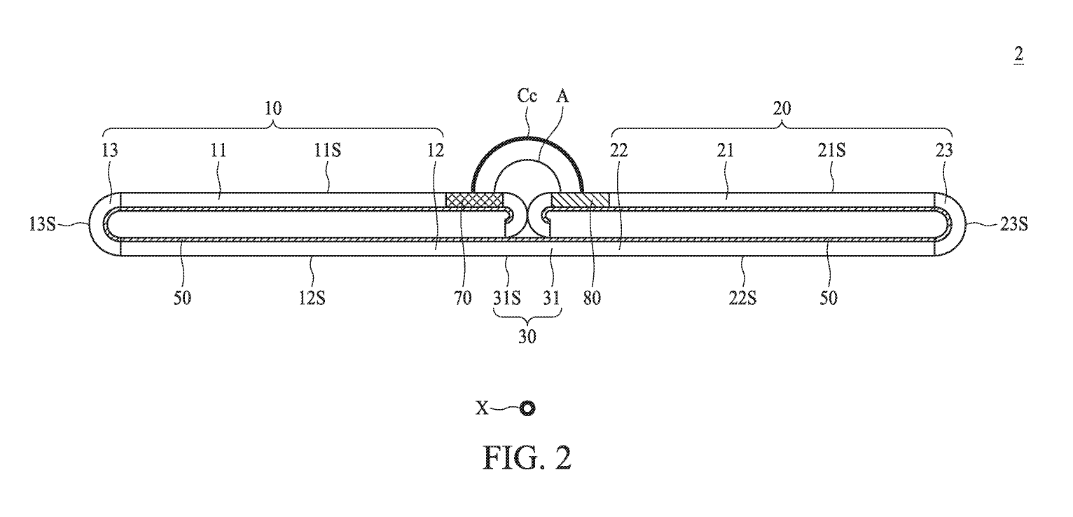

FIG. 2 is a schematic diagram of a foldable electronic device in accordance with some embodiments of the present disclosure. As depicted in FIG. 2, the foldable electronic device 2 may further include at least one display panel 50 disposed in the first electronic component 10 and the second electronic component 20. The display panel 50 is configured to display images from the first surface 11S, the second surface 12S, the third surface 21S and the third surface 225. In some embodiments, the display panel 50 may further be configured to display images from the fifth surface 31S, the first curve surface 13S and the second curve surface 23S. In some embodiments, the display panel 50 may include a rigid display panel, a flexible display panel or a bendable display panel such as a liquid crystal display (LCD) panel, an organic light-emitting diode (OLED) display panel, an electrophoretic display (EPD) panel or the like. The foldable electronic device 2 may be folded at different folding angles A as illustrated in FIGS. 1A-1G. The foldable electronic component 2 is advantageous due to it high screen ratio.

When the user folds the foldable electronic device 1, the folding angle A can be detected, and a respective display mode may be enabled according to the folding angle A to meet the user's requirement. When the user folds the foldable electronic device 2, the folding angle A can be detected, and a corresponding display mode and/or touch input mode may be enabled to meet the user's requirement. For example, when the foldable electronic device 2 is unfolded, the display and/or touch input function of the first surface 11S, the second surface 12S, the third surface 21S and the fourth surface 22S can be enabled. When the foldable electronic device 2 is folded at a folding angle A of about 90 degrees, the display and/or touch input function of the first surface 115 and the third surface 215 can be enabled, while the display and/or touch input function the second surface 12S and the fourth surface 225 can be disabled.

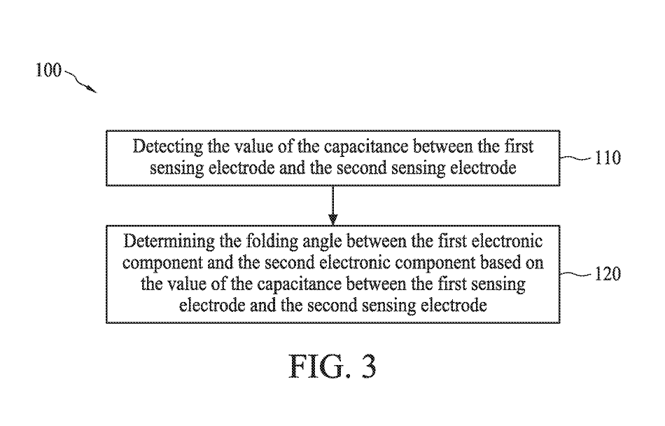

Referring to FIG. 3 as well as FIGS. 1A-2, FIG. 3 is a flow chart illustrating a method for controlling a foldable electronic device according to various aspects of one or more embodiments of the present disclosure. The method 100 begins with operation 110 in which the value of the capacitance Cc between the first sensing electrode 70 and the second sensing electrode 80 is detected. The method 100 proceeds with operation 120 in which the folding angle A between the first electronic component 10 and the second electronic component 20 is determined based on the value of the capacitance Cc between the first sensing electrode 70 and the second sensing electrode 80.

In some embodiments of the present disclosure, the foldable electronic device may include a foldable touch device and/or a foldable display device. The foldable electronic device includes first sensing electrode(s) and second sensing electrode(s) disposed in the first and second electronic components, respectively. The folding angle of the foldable electronic device can be determined by the value of capacitance between the first sensing electrode(s) and the second sensing electrode(s), and corresponding operation mode such as touch input mode and/or display mode can be automatically selected according to the detected folding angle to meet the user's requirement.

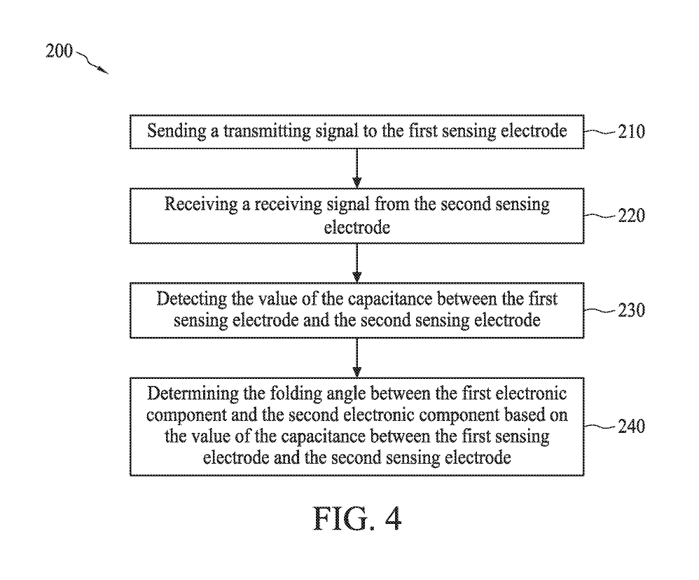

In some embodiments, the first sensing electrode 70 and the second sensing electrode 80 are driven in a mutually capacitive manner, and the first sensing electrode 70 and the second sensing electrode 80 may be configured as a transmitting electrode and a receiving electrode, respectively. Referring to FIG. 4 as well as FIGS. 1A-2, FIG. 4 is a flow chart illustrating a method for controlling a foldable electronic device according to various aspects of one or more embodiments of the present disclosure. The method 200 begins with operation 210 in which a transmitting signal is sent to the first sensing electrode 70. The method 200 proceeds with operation 220 in which a receiving signal coupled by the transmitting signal is received by the second sensing electrode 80. The method 200 proceeds with operation 230 in which the value of the capacitance Cc between the first sensing electrode 70 and the second sensing electrode 80 is detected. The method 200 proceeds with operation 240 in which the folding angle A between the first electronic component 10 and the second electronic component 20 is determined based on the value of the capacitance Cc between the first sensing electrode 70 and the second sensing electrode SO.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein, Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A foldable electronic device, comprising:
a first electronic component including a first surface and a second surface opposite to the first surface;
a first sensing electrode in the first electronic component;
a second electronic component including a third surface and a fourth surface opposite to the third surface;
a second sensing electrode in the second electronic component; and
a foldable component connected between the first electronic to component and the second electronic component, and the foldable component is configured for folding the first electronic component with respect to the second electronic component about an axis, wherein a capacitance is formed between the first sensing electrode and the second sensing electrode, and a folding angle between the first electronic is component and the second electronic component is determined based on a value of the capacitance between the first sensing electrode and the second sensing electrode.

2. The foldable electronic device of claim 1, wherein the first surface, the second surface, the third surface and the fourth surface are flat surfaces.

3. The foldable electronic device of claim 1, wherein the first electronic component comprises a first touch component configured to implement touch input function from the first surface.

4. The foldable electronic device of Claim I, wherein the first electronic component comprises a second touch component configured to implement touch input function from the second surface,

5. The foldable electronic device of claim 1, wherein the second electronic component comprises a third touch component configured to implement touch input function from the third surface.

6. The foldable electronic device of claim 1, wherein the second electronic component comprises a fourth touch component configured to implement touch input function from the fourth surface.

7. The foldable electronic device of claim 1, wherein the foldable component further includes a fifth surface connected between the second surface and the fourth surface, and a fifth touch component configured to implement touch input function from the fifth surface.

8. The foldable electronic device of claim 7, wherein when the folding angle is substantially equal to 180 degrees, the fifth surface is a flat surface.

9. The foldable electronic device of claim 7, wherein when the folding angle is smaller than 180 degrees, the fifth surface is a curve surface.

10. The foldable electronic device of claim 1. wherein the first electronic component further includes a first curve surface connected between the first surface and the second surface, and a first curve touch component configured to implement touch input function from the first curve surface.

11. The foldable electronic device of claim 1, wherein the second electronic component further includes a second curve surface connected between the third surface and the fourth surface, and a second curve touch component configured to implement touch input function from the second curve surface.

12. The foldable electronic device of claim 1, further comprising at least one display panel disposed in the first electronic component and the second electronic component, and configured to display images from the first surface, the second surface, the third surface and the third surface.

13. A method for controlling the foldable electronic device of claim 1, comprising:
detecting the value of the capacitance between the first sensing electrode and the second sensing electrode; and
to determining the folding angle between the first electronic component and the second electronic component based on the value of the capacitance between the first sensing electrode and the second sensing electrode.

14. The method of claim 13, further comprising:
sending a transmitting signal to the first sensing electrode; and
receiving a receiving signal by the second sensing electrode.

15. The method of claim 13, wherein the foldable electronic device comprises a foldable touch device, and the method further comprises enabling a respective touch input mode according to the folding angle between the first electronic component and the second electronic component.

16. The method of claim 13, wherein the foldable electronic device comprises a foldable display device, and the method further comprises switching the foldable electronic device to a respective display mode according to the folding angle between the first electronic component and the second electronic component.
